(19) United States
(12) Patent Application Publication
(10) Pub. No.: US 2015/0257316 A1
(43) Pub. Date: Sep. 10, 2015

(54) METHOD OF MAKING THERMALLY ENHANCED WIRING BOARD HAVING ISOLATOR INCORPORATED THEREIN

(71) Applicant: BRIDGE SEMICONDUCTOR CORPORATION, Taipei (TW)

(72) Inventors: Charles W. C. Lin, Singapore (SG); Chia-Chung Wang, Hsinchu County (TW)

(21) Appl. No.: 14/621,332

(22) Filed: Feb. 12, 2015

Related U.S. Application Data
(60) Provisional application No. 61/949,652, filed on Mar. 7, 2014.

(51) Int. Cl. H05K 13/00; H05K 13/04

(52) U.S. Cl. CPC H05K 13/0023; H05K 13/0469; H05K 13/0486

(57) ABSTRACT

A method of making a wiring board having a low CTE isolator incorporated in a resin core is characterized by the provision of an adhesive substantially coplanar with the metallized isolator and the metal layers on two opposite sides of the resin core at smoothed lapped top and bottom surfaces so that a metal bridge can be deposited on the adhesive at the smoothed lapped bottom surface and connect the metallized isolator with a surrounding heat spreader on the bottom surface of the resin core. In the method, routing circuitries are also deposited on the adhesive at the smoothed lapped top surface so as to provide electrical connections between contact pads on the isolator and terminal pads on the resin core.

### CROSS REFERENCE TO RELATED APPLICATIONS

This application claims the benefit of filing date of U.S. Provisional Application Ser. No. 61/949,652 filed Mar. 7, 2014. The entirety of said Provisional application is incorporated herein by reference.

### FIELD OF THE INVENTION

The present invention relates to a method of making a wiring board, and more particularly to a method of making a thermally enhanced wiring board having an isolator incorporated in a resin core and thermally conductible to a heat spreader.

### DESCRIPTION OF RELATED ART

High voltage or high current applications such as power modules, microprocessors or light emitted diodes (LED) often require high performance wiring board to interconnect electrical signals for specific functions. However, as the power increases, large amount of heat generated by semiconductor chip would degrade device performance and imposes thermal stress on the chip. Ceramic materials, such as alumina or aluminum nitride which is an electrical insulator and has low CTE (Coefficient of Thermal Expansion), are often considered as suitable materials for semiconductor chip interconnect base. U.S. Pat. Nos. 8,895,998 and 7,670,872 disclose various interconnect structures using ceramic as the isolator material for better reliability. Although ceramic has a low CTE which is adequate for semiconductor chip attachment, its thermal conductivity (e.g., about 20 W/m·k for Al₂O₃ and about 150 W/m·k for AIN) is too low for high power applications where large amount of heat needs to be dissipated effectively during operation.

For the reasons stated above, and for other reasons stated below, an urgent need exists to develop a new thermally enhanced wiring board that can address device reliability concerns and also provides high thermal conducting capability.

### SUMMARY OF THE INVENTION

A primary objective of the present invention is to provide a wiring board having a low CTE isolator embedded in a resin core so as to resolve the chip/board CTE mismatch problem, thereby improving the mechanical reliability of the semiconductor assembly.

Another objective of the present invention is to provide a wiring board in which the isolator is thermally conductible to a surrounding heat spreader through a metal bridge so that the heat transferred to the isolator can be further spread out to the entire board, thereby improving the thermal dissipation of the semiconductor assembly.

Yet another objective of the present invention is to provide a wiring board in which routing circuitries on the isolator extend to the resin core, thereby allowing fine pitch assemblies such as flip chip to be assembled on the isolator and interconnected to the external environment at the resin core.

In accordance with the foregoing and other objectives, the present invention proposes a wiring board having an isolator, a resin core, a wiring layer, a metal joint and a heat spreader. The isolator provides CTE-compensated contact interface for a semiconductor chip, and also provides primary heat conduction for the chip so that the heat generated by the chip can be conducted away before further spreading to the heat spreader. The resin core, which provides mechanical support for the isolator, the heat spreader and the wiring layer, serves as a spacer between the wiring layer and the heat spreader. The heat spreader, thermally conductible to the isolator through the metal joint at the bottom surface of the wiring board, provides a heat spreading platform that is larger than the isolator so that the heat transferred to the isolator can be further spread out. The wiring layer, disposed on the top surfaces of the isolator and the resin core, provides signal transmission and electrical routing of the board.

In one aspect, the present invention proposes a method of making a thermally enhanced wiring board, comprising the steps of: providing an isolator having opposite planar first and second sides, wherein the isolator is made of a thermally conductive and electrically insulating material; depositing first and second metal films respectively on the first and second sides of the isolator to provide a metallized isolator; providing a stacking structure that includes first and second metal layers, a binding film disposed between the first and second metal layers, and an aperture formed in the stacking structure, wherein the first and second metal layers each have a planar surface; inserting the metallized isolator into the aperture of the stacking structure with the first metal film on the isolator and the first metal layer of the stacking structure facing towards the same direction, and then curing the binding film to form a resin core that has a first side bonded to the first metal layer and an opposite second side bonded to the second metal layer, wherein the stacking structure is adhered to sidewalls of the metallized isolator by an adhesive squeezed out from the binding film into a gap between the stacking structure and the metallized isolator; removing an excess portion of the squeezed out adhesive, thereby the adhesive having a first surface substantially coplanar with the first metal film on the isolator and the first metal layer of the stacking structure, and an opposite second surface substantially coplanar with the second metal film on the isolator and the second metal layer of the stacking structure; depositing a continuous thermally conductive joint layer on the first surface of the adhesive, the first metal film and the first metal layer, to connect the first metal film on the isolator to the first metal layer on the resin core; and forming contact pads on the second side of the isolator, terminal pads on the second side of the resin core, and routing circuitries that electrically connect the contact pads to the terminal pads.

In another aspect, the present invention proposes another method of making a thermally enhanced wiring board, comprising the steps of: providing an isolator having opposite planar first and second sides, wherein the isolator is made of a thermally conductive and electrically insulating material; depositing first and second metal films respectively on the first and second sides of the isolator to provide a metallized isolator; providing a laminate substrate that includes a resin core, first and second metal layers respectively disposed on opposite first and second sides of the resin core, and an aperture formed in the laminate substrate, wherein the first and second metal layers each have a planar surface; inserting the metallized isolator into the aperture of the laminate substrate with the first metal film on the isolator and the first metal layer of the laminate substrate facing towards the same direction, and then dispensing an adhesive into a gap between the metallized isolator and the laminate substrate within the aperture to adhere sidewalls of the metallized isolator to sidewalls of the aperture; removing an excess portion of the adhesive, thereby the adhesive having a first surface substantially coplanar with the first metal film on the isolator and the first metal layer of the laminate substrate, and an opposite second surface substantially coplanar with the second metal film on the isolator and the second metal layer of the laminate substrate; depositing a continuous thermally conductive joint layer on the first surface of the adhesive, the first metal film and the first metal layer, to connect the first metal film on the isolator to the first metal layer on the resin core; and forming contact pads on the second side of the isolator, terminal pads on the second side on the resin core, and routing circuitries that electrically connect the contact pads to the terminal pads.

In yet another aspect, the present invention proposes yet another method of making a thermally enhanced wiring board, comprising the steps of: attaching an isolator on a carrier film, wherein the isolator is made of a thermally conductive and electrically insulating material and has opposite planar first and second sides; depositing a dielectric layer that covers the isolator and the carrier film; removing a portion of the dielectric layer to form a resin core that has a first side and an opposite second side substantially coplanar with the second side of the isolator, and detaching the carrier film therefrom; depositing a continuous thermally conductive joint layer on the first side of the isolator and the first side of the resin core; and forming contact pads on the second side of the isolator, terminal pads on the second side of the resin core, and routing circuitries that electrically connect the contact pads to the terminal pads.

Unless specific descriptions or using the term “then” between steps or steps necessarily occurring in a certain order, the sequence of the above-mentioned steps is not limited to that set forth above and may be changed or reordered according to desired design.

The method of making a thermally enhanced wiring board according to the present invention has numerous advantages. For instance, depositing the joint layer to connect the isolator to a surrounding heat spreader can establish a larger thermal dissipation surface area than the isolator so that the tedious process of fusing a large and thick copper plate to the isolator can be avoided, thereby minimizing manufacturing complexity and reducing cost. Binding the resin core to the isolator can provide a platform for high resolution circuitries disposed thereon, thereby allowing fine pitch assemblies such as flip chip and surface mount component to be assembled on the board.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIG. 1 is a cross-sectional view of an isolator in accordance with the first embodiment of the present invention;

FIG. 2 is a cross-sectional view of a metallized isolator in accordance with the first embodiment of the present invention;

FIG. 3 is a cross-sectional view of a stacking structure on a carrier film in accordance with the first embodiment of the present invention;

FIG. 4 is a cross-sectional view showing the metallized isolator of FIG. 2 is attached to the carrier film of FIG. 3 in accordance with the first embodiment of the present invention;

FIGS. 5 and 6 are cross-sectional and top perspective views, respectively, showing the stacking structure of FIG. 4 is subjected to a lamination process in accordance with the first embodiment of the present invention;

FIGS. 7 and 8 are cross-sectional and top perspective views, respectively, showing excess adhesive is removed from the structures of FIGS. 6 and 7 in accordance with the first embodiment of the present invention;

FIG. 9 is a cross-sectional view showing the carrier film is removed from the structure of FIG. 7 in accordance with the first embodiment of the present invention;

FIGS. 10 and 11 are cross-sectional and top perspective views, respectively, showing the structure of FIG. 9 is provided with a joint layer and a wiring layer to finish the fabrication of a wiring board in accordance with the first embodiment of the present invention;

FIG. 12 is a cross-sectional view of an assembly with a chip mounted on the wiring board of FIG. 10 in accordance with the first embodiment of the present invention;

FIG. 13 is a cross-sectional view of a stacking structure on a carrier film in accordance with the second embodiment of the present invention;

FIG. 14 is a cross-sectional view showing the metallized isolator of FIG. 2 is attached to the carrier film of FIG. 13 in accordance with the second embodiment of the present invention;

FIG. 15 is a cross-sectional view showing the stacking structure of FIG. 14 is subjected to a lamination process in accordance with the second embodiment of the present invention;

FIG. 16 is a cross-sectional view showing excess adhesive and the carrier film are removed from the structure of FIG. 15 in accordance with the second embodiment of the present invention;

FIGS. 17 and 18 are cross-sectional and top perspective views, respectively, showing the structure of FIG. 16 is provided with a joint layer and a wiring layer to finish the fabrication of a wiring board in accordance with the second embodiment of the present invention;

FIG. 19 is a cross-sectional view of a laminate substrate on a carrier film in accordance with the third embodiment of the present invention;

FIG. 20 is a cross-sectional view showing the metallized isolator of FIG. 2 is attached to the carrier film of FIG. 19 in accordance with the third embodiment of the present invention;

FIG. 21 is a cross-sectional view showing the structure of FIG. 20 is provided with an adhesive in accordance with the third embodiment of the present invention;

FIG. 22 is a cross-sectional view showing excess adhesive and the carrier film are removed from the structure of FIG. 21 in accordance with the third embodiment of the present invention;

FIGS. 23 and 24 are cross-sectional and top perspective views, respectively, showing the structure of FIG. 22 is provided with a joint layer and a wiring layer to finish the fabrication of a wiring board in accordance with the third embodiment of the present invention;

FIG. 25 is a cross-sectional view of a metal plate on a carrier film in accordance with the fourth embodiment of the present invention;

FIG. 26 is a cross-sectional view showing an isolator is attached to the carrier film of FIG. 25 in accordance with the fourth embodiment of the present invention;

FIG. 27 is a cross-sectional view showing the structure of FIG. 26 is provided with a dielectric layer in accordance with the fourth embodiment of the present invention;

FIG. 28 is a cross-sectional view showing the upper portion of the dielectric layer is removed from the structure of FIG. 27 in accordance with the fourth embodiment of the present invention;

FIG. 29 is a cross-sectional view showing the carrier film is removed from the structure of FIG. 28 in accordance with the fourth embodiment of the present invention; and

FIGS. 30 and 31 are cross-sectional and top perspective views, respectively, showing the structure of FIG. 29 is provided with a joint layer and a wiring layer to finish the fabrication of a wiring board in accordance with the fourth embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the disclosure of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

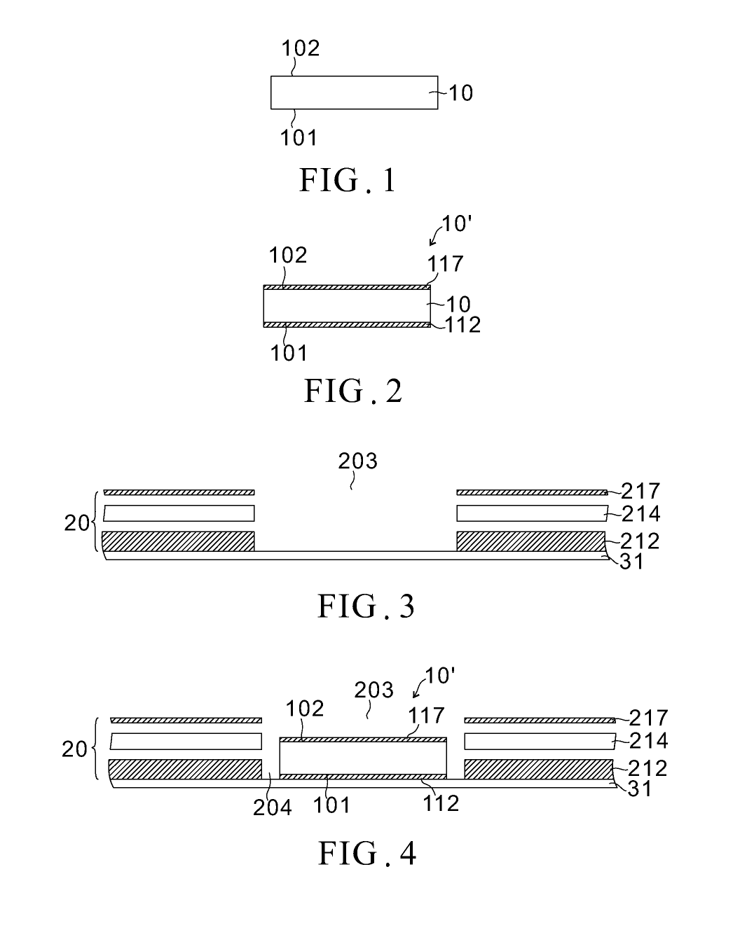

FIGS. 1-11 are schematic views showing a method of making a thermally enhanced wiring board that includes an isolator, a resin core, a thermal base, contact pads, terminal pads and routing circuitries in accordance with an embodiment of the present invention.

FIG. 1 is a cross-sectional view of an isolator 10 having opposite planar first and second sides 101, 102. The isolator 10 typically has high elastic modulus and low coefficient of thermal expansion (for example, 2×10⁻⁶ K⁻¹ to 10×10⁻⁶ K⁻¹), such as ceramic, silicon, glass or other thermally conductive and electrically insulating materials. In this embodiment, the isolator 10 is a ceramic plate of 0.4 mm in thickness.

FIG. 2 is a cross-sectional view of a metallized isolator 10′ having a first film 112 and a second film 117 respectively deposited on the first and second sides 101, 102 of the isolator 10. The first metal film 112 and the second metal film 117 are typically made of copper and each have a thickness of 35 microns.

FIG. 3 is a cross-sectional view of a stacking structure 20 having an aperture 203 on a carrier film 31. The stacking structure 20 includes a first metal layer 212, a binding film 214 and a second metal layer 217. The aperture 203 is formed by punching through the first metal layer 212, the binding film 214 and the second metal layer 217, and has a dimension that is almost the same or a little larger than the metallized isolator 10′. Also, the aperture 203 may be formed by other techniques such as laser cutting with or without wet etching. The carrier film 31 typically is a tape, and the first metal layer 212 is attached to the carrier film 31 by the adhesive property of the carrier film 31. In this stacking structure 20, the binding film 214 is disposed between the first metal layer 212 and the second metal layer 217. The first metal layer 212 and the second metal layer 217 are typically made of copper. The binding film 214 can be various dielectric films or prepregs formed from numerous organic or inorganic electrical insulators. For instance, the binding film 214 can initially be a prepreg in which thermosetting epoxy in resin form impregnates a reinforcement and is partially cured to an intermediate stage. The epoxy can be FR-4 although other epoxies such as polyfunctional and bismaleimide triazine (BT) are suitable. For specific applications, cyanate esters, polyimide and PTFE are also suitable. The reinforcement can be E-glass although other reinforcements such as S-glass, D-glass, quartz, kevlar aramid and paper are suitable. The reinforcement can also be woven, non-woven or random microfiber. A filler such as silica (powdered fused quartz) can be added to the prepreg to improve thermal conductivity, thermal shock resistance and thermal expansion matching Commercially available prepregs such as SPEEDBOARD C prepreg by W.L. Gore & Associates of Eau Claire, Wis. are suitable. In this embodiment, the binding film 214 is a prepreg with B-stage uncured epoxy provided as a non-solidified sheet, and the first metal layer 212 and the second metal layer 217 are copper layers of 0.2 mm and 0.025 mm in thickness, respectively.

FIG. 4 is a cross-sectional view of the structure with the metallized isolator 10′ attached on the carrier film 31. The metallized isolator 10′ is aligned with the aperture 203 of the stacking structure 20 with the first metal film 112 facing towards the carrier film 31, and is inserted into the aperture 203 without contacting the stacking structure 20. As a result, a gap 204 is located in the aperture 203 between the metallized isolator 10′ and the stacking structure 20. The gap 204 laterally surrounds the metallized isolator 10′ and is laterally surrounded by the stacking structure 20. In this illustration, the metallized isolator 10′ is attached to the carrier film 31 by the adhesive property of the carrier film 31. Also, the metallized isolator 10′ may be attached to the carrier film 31 by dispensing extra adhesive.

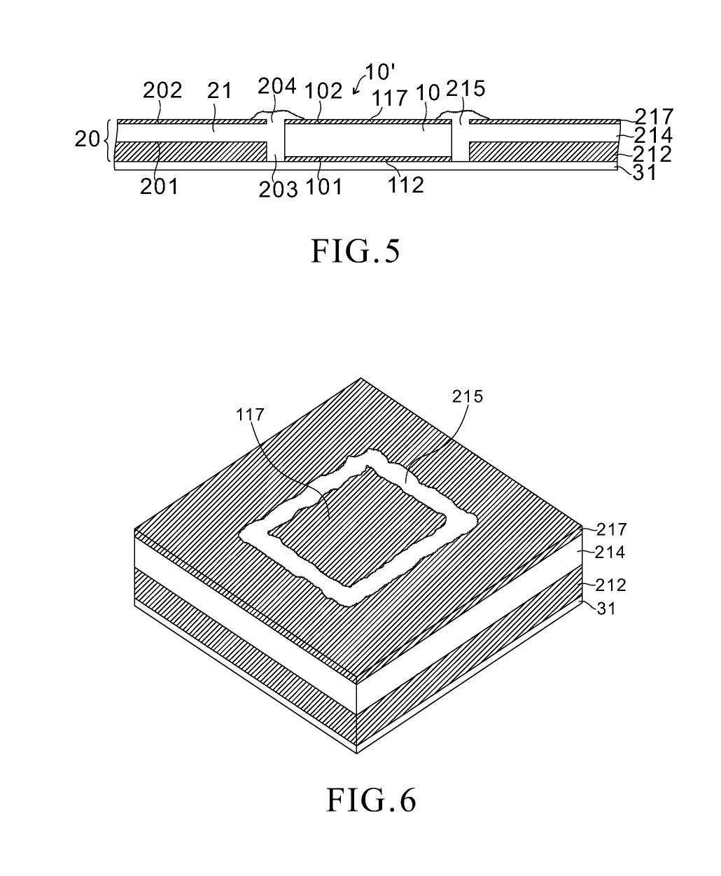

FIGS. 5 and 6 are cross-sectional and top perspective views, respectively, of the structure in which the gap 204 is filled with an adhesive 215 squeezed out from the binding film 214. By applying heat and pressure, the binding film 214 is squeezed and part of the adhesive in the binding film 214 flows into the gap 204. The bonding film 214 is compressed by applying downward pressure to the second metal layer 217 and/or upward pressure to the carrier film 31, thereby moving the first metal layer 212 and the second metal layer 217 towards one another and applying pressure to the binding film 214 while simultaneously applying heat to the binding film 214. The binding film 214 becomes compliant enough under the heat and pressure to conform to virtually any shape. As a result, the binding film 214 sandwiched between the first metal layer 212 and the second metal layer 217 is compressed, forced out of its original shape and flows into the gap 204. The first metal layer 212 and the second metal layer 217 continue to move towards one another, and the binding film 214 remains sandwiched between and continues to fill the reduced space between the first metal layer 212 and the second metal layer 217. Meanwhile, the adhesive 215 squeezed out from the binding film 214 fills the gap 204. In this illustration, the adhesive 215 squeezed out from the binding film 214 also rises slightly above the aperture 203 and overflows onto the top surfaces of the second metal film 117 and the second metal layer 217. This may occur due to the binding film 214 being slightly thicker than necessary. As a result, the adhesive 215 squeezed out from the binding film 214 creates a thin coating on the top surfaces of the second metal film 117 and the second metal layer 217. The motion eventually stops when the second metal layer 217 becomes coplanar with the second metal film 117 at the top surface, but heat continues to be applied to the binding film 214 and the squeezed out adhesive 215, thereby converting the B-stage molten uncured epoxy into C-stage cured or hardened epoxy.

At this stage, the stacking structure 20 is bonded with sidewalls of the metallized isolator 10′ by the adhesive 215 squeezed out from the binding film 214. The binding film 214 as solidified provides a secure robust mechanical bond between the first metal layer 212 and the second metal layer 217. Accordingly, the isolator 10 is incorporated with a resin core 21 that has a first side 201 bonded to the first metal layer 212 and an opposite second side 202 bonded to the second metal layer 217. The first and second metal layers 212, 217 each have a planar surface and are coplanar with the first and second metal films 112, 117 in the downward and upward directions, respectively.

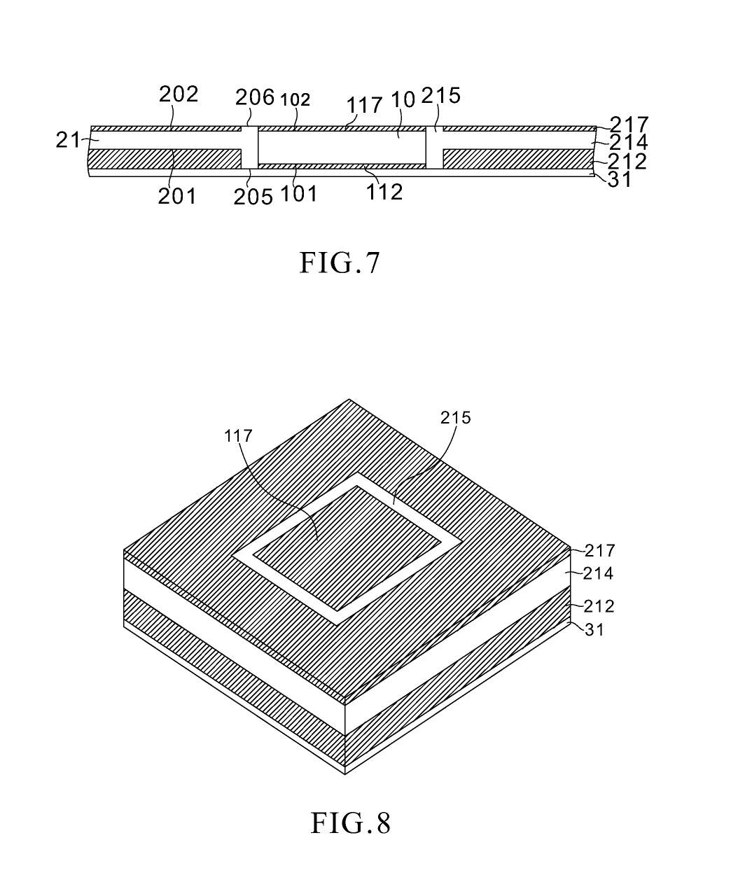

FIGS. 7 and 8 are cross-sectional and top perspective views, respectively, of the structure after removal of excess adhesive that overflows onto the second metal film 117 and second metal layer 217. The excess adhesive can be removed by lapping/grinding. After lapping/grinding, the second metal film 117 on the isolator 10, the second metal layer 217 on the resin core 21 and the adhesive 215 squeezed out from the binding film 214 are essentially coplanar with one another at a smoothed lapped top surface. Accordingly, the adhesive 215 has a first surface 205 essentially coplanar with the first metal film 112 and the first metal layer 212 in the downward direction, and an opposite second surface 206 essentially coplanar with the second metal film 117 and the second metal layer 217 in the upward direction.

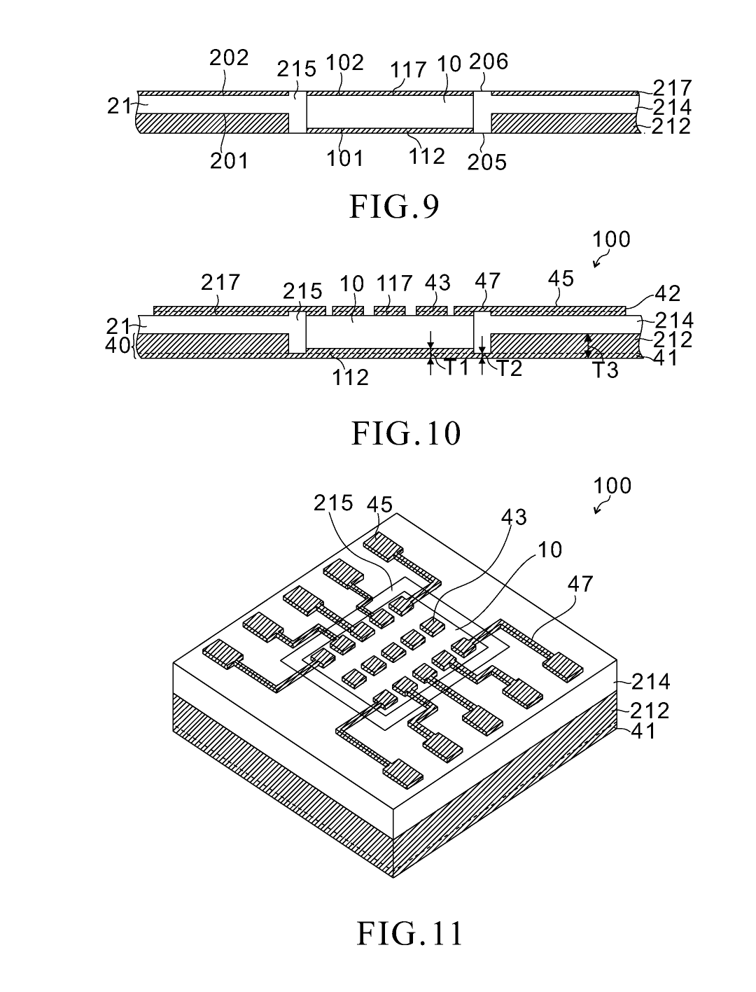

FIG. 9 is a cross-sectional view of the structure after removal of the carrier film 31. The carrier film 31 is detached from the first metal film 112, the first metal layer 212 and the squeezed out adhesive 215 to expose the first metal film 112 and the first metal layer 212.

FIGS. 10 and 11 are cross-sectional and top perspective views, respectively, of the structure provided with a continuous thermally conductive joint layer 41, contact pads 43, terminal pads 45 and routing circuitries 47. The bottom surface of the structure can be metallized to form the joint layer 41 as a single layer or multiple layers by numerous techniques, such as electroplating, electroless plating, evaporating, sputtering or their combinations. For instance, the structure can be first dipped in an activator solution to render the bottom surface of the structure catalytic to electroless copper, then a thin copper layer is electrolessly plated to serve as the seeding layer before a second copper layer is electroplated on the seeding layer to a desirable thickness. Alternatively, the seeding layer can be formed by sputtering a thin film such as titanium/copper onto the bottom surface of the structure before depositing the electroplated copper layer on the seeding layer. The joint layer 41 is an unpatterned metal layer (typically a copper layer) that contacts the first metal film 112, the first metal layer 212 and the squeezed out adhesive 215 at the bottom surface and covers them from below. In this illustration, the first metal film 112, the first metal layer 212 and the joint layer 41 are shown as a single layer for convenience of illustration. The boundary (shown in dashed line) between the metal layers may be difficult or impossible to detect since copper is plated on copper. However, the boundary between the joint layer 41 and the squeezed out adhesive 215 is clear.

Also, the top surface of the structure can be metallized to form a plated layer 42 by the same activator solution, electroless copper seeding layer and electroplated copper layer. Once the desired thickness is achieved, a metal patterning process is executed to form the contact pads 43, the terminal pads 45 and the routing circuitries 47. The contact pads 43 and the terminal pads 45 are respectively disposed on the second side 102 of the isolator 10 and the second side 202 of the resin core 21. The routing circuitries 47 extend laterally on the second side 102 of the isolator 10, the second surface 206 of the adhesive 215 and the second side 202 of the resin core 21 and contacts the contact pads 43 and the terminal pads 45. The metal patterning techniques include wet etching, electro-chemical etching, laser-assist etching, and their combinations with an etch mask (not shown) thereon that defines the contact pads 43, the terminal pads 45 and the routing circuitries 47.

Accordingly, as shown in FIGS. 10 and 11, a thermally enhanced wiring board 100 is accomplished and includes an isolator 10, a resin core 21, a squeezed out adhesive 215, a thermal base 40, contact pads 43, terminal pads 45 and routing circuitries 47. The resin core 21 is mechanically connected to sidewalls of the isolator 10 by the squeezed out adhesive 215. The thermal base 40 includes the first metal film 112, the first metal layer 212 and the joint layer 41, and has a first thickness T1 where it contacts the isolator 10, a second thickness T2 where it contacts the squeezed out adhesive 215, a third thickness T3 where it contacts the resin core 21, and a flat surface that faces in the downward direction. In this illustration, the first thickness T1 and the third thickness T3 are larger than the second thickness T2, and the third thickness T3 is larger than the first thickness T1. The contact pads 43 have a combined thickness of the second metal film 117 and the plated layer 42 thereon and can serve as electrical contacts for chip attachment. The terminal pads 45 have a combined thickness of the second metal layer 217 and the plated layer 42 thereon and can serve as electrical contacts for external connections. The routing circuitries 47 has a thickness of the plated layer 42 where it contacts the squeezed out adhesive 215, a combined thickness of the second metal film 117 and the plated layer 42 thereon where it contacts the isolator 10, and a combined thickness of the second metal layer 217 and the plated layer 42 thereon where it contacts the resin core 21. The routing circuitries 47 provide an electrical connection between the contact pads 43 and the terminal pads 45.

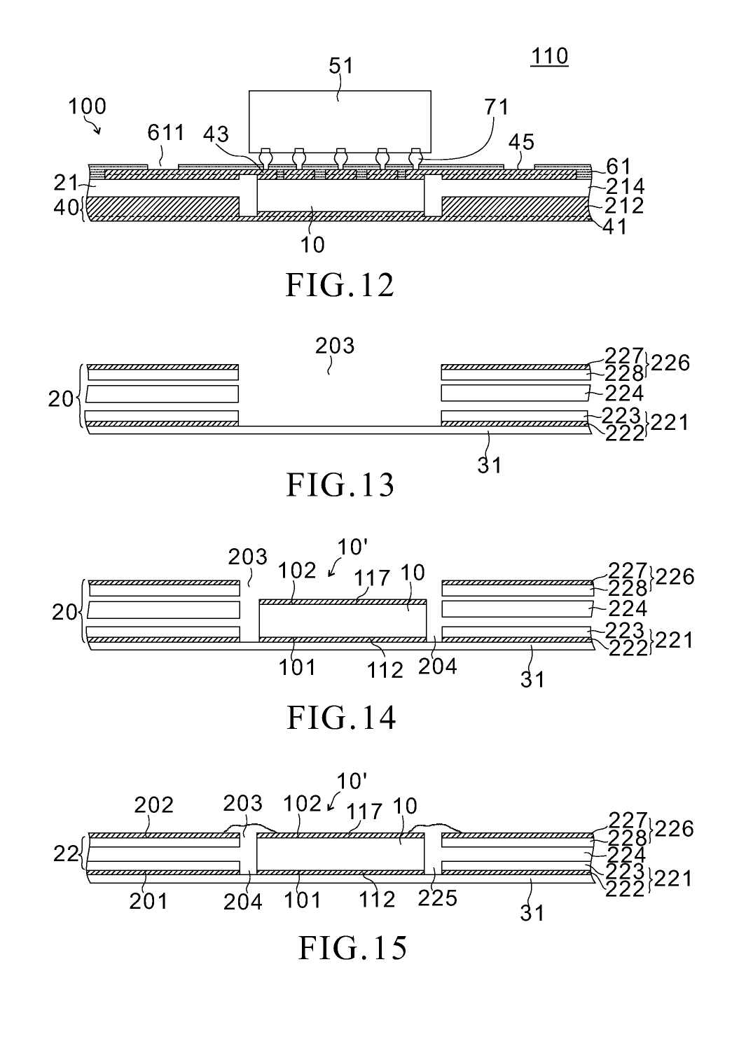

FIG. 12 is a cross-sectional view of an LED assembly 110 with an LED chip 51 mounted on the thermally enhanced wiring board 100 illustrated in FIG. 11. In this illustration, the wiring board 100 is further provided with a solder mask layer 61 on its top surface. The solder mask layer 61 includes solder mask openings 611 to expose the contact pads 43 and the terminal pads 45. The LED chip 51 is flip-chip mounted on the exposed contact pads 43 of the wiring board 100 via solder bumps 71. Accordingly, the isolator 10 can provide CTE-buffered contact interface for the LED chip 51, and the heat generated by the LED chip 51 can be transferred to the isolator 10 and further spread out to a surrounding heat spreader composed of the first metal layer 212 and a portion of the joint layer 41 adjacent to the first metal layer 212.

### Embodiment 2

FIGS. 13-18 are schematic views showing another method of making a thermally enhanced wiring board in which another stacking structure is provided to form a resin core in accordance with another embodiment of the present invention.

For purposes of brevity, any description in Embodiment 1 above is incorporated herein insofar as the same is applicable, and the same description need not be repeated.

FIG. 13 is a cross-sectional view of the structure with a stacking structure 20 on a carrier film 31. The stacking structure 20 includes a first laminate substrate 221, a binding film 224 and a second laminate substrate 226. The stacking structure 20 has an aperture 203 that extends through the first laminate substrate 221, the binding film 224 and the second laminate substrate 226. In this illustration, the first laminate substrate 221 includes a first metal layer 222 disposed on a first dielectric layer 223, and the second laminate substrate 226 includes a second metal layer 227 disposed on a second dielectric layer 228. The first and second dielectric layers 223, 228 typically are made of epoxy resin, glass-epoxy, polyimide or the like, and have a thickness of 50 microns. The first and second metal layers 222, 227 typically are made of copper and have a thickness of 35 microns. In this stacking structure 20, the binding film 224 is disposed between the first laminate substrate 221 and the second laminate substrate 226, and the first metal layer 222 of the first laminate substrate 221 and the second metal layer 227 of the second laminate substrate 226 respectively face in the downward and upward directions. By the adhesive property of the carrier film 31, the stacking structure 20 is attached to the carrier film 31 with the first metal layer 222 of the first laminate substrate 221 in contact with the carrier film 31.

FIG. 14 is a cross-sectional view of the structure with the metallized isolator 10′ of FIG. 2 attached to the carrier film 31. The metallized isolator 10 is inserted into the aperture 203 of the stacking structure 20 with the first metal film 112 facing towards the carrier film 31 and is attached to the carrier film 31 without contacting the stacking structure 20. As a result, a gap 204 is located in the aperture 203 between the metallized isolator 10′ and the stacking structure 20.

FIG. 15 is a cross-sectional view of the structure in which the gap 204 is filled with an adhesive 225 squeezed out from the binding film 224. By applying heat and pressure, the binding film 224 is squeezed and part of the adhesive in the binding film 224 flows into the gap 204. After the squeezed out adhesive 225 fills up the gap 204, the binding film 224 and the squeezed out adhesive 225 are solidified. Accordingly, the isolator 10 is bonded to a resin core 22 by the squeezed out adhesive 225 in the gap 204. In this embodiment, the resin core 22 includes the first dielectric layer 223, the cured binding film 224 and the second dielectric layer 228, and has a first side 201 bonded to the first metal layer 222 and an opposite second side 202 bonded to the second metal layer 227. The cured binding film 224 is integrated with the first dielectric layer 223 of the first laminate substrate 221 and the second dielectric layer 228 of the second laminate substrate 226, and provides secure robust mechanical bonds between the first laminate substrate 221 and the second laminate substrate 226. The squeezed out adhesive 225 in the gap 204 provides secure robust mechanical bonds between the isolator 10 and the resin core 22. In this illustration, the adhesive 225 squeezed out from the binding film 224 also rises slightly above the aperture 203 and overflows onto the top surfaces of the second metal film 117 and the second metal layer 227.

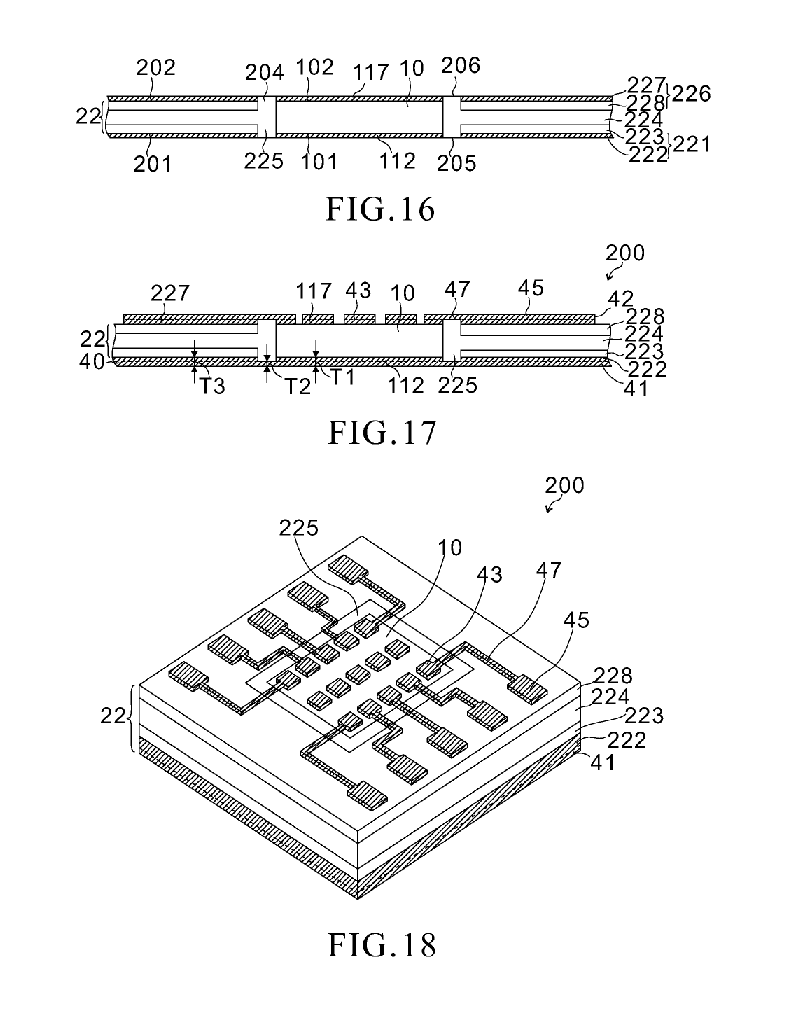

FIG. 16 is a cross-sectional view of the structure after removal of excess adhesive and the carrier film 31. The excess adhesive on the second metal film 117 and second metal layer 227 is removed by lapping/grinding to create a smoothed lapped top surface. The carrier film 31 is detached from the first metal film 112, the first metal layer 222 and the squeezed out adhesive 225 to expose the first metal film 112 and the first metal layer 222. In this illustration, the squeezed out adhesive 225 has a first surface 205 essentially coplanar with the first metal film 112 and the first metal layer 222 in the downward direction, and an opposite second surface 206 essentially coplanar with the second metal film 117 and the second metal layer 227 in the upward direction.

FIGS. 17 and 18 are cross-sectional and top perspective views, respectively, of the structure provided with a continuous thermally conductive joint layer 41, contact pads 43, terminal pads 45 and routing circuitries 47. The bottom surface of the structure is metallized to form the joint layer 41 that contacts and covers the first metal film 112 on the isolator 10, the first metal layer 222 on the resin core 22 and the squeezed out adhesive 225 from below. Also, the top surface of the structure is metallized to form a plated layer 42, followed by a metal patterning process to form the contact pads 43, the terminal pads 45 and the routing circuitries 47. The contact pads 43 and the terminal pads 45 are disposed on the second side 102 of the isolator 10 and the second side 202 of the resin core 22, respectively. The routing circuitries 47 extend laterally on the second side 102 of the isolator 10, the second surface 206 of the squeezed out adhesive 225 and the second side 202 of the resin core 22 and contacts the contact pads 43 and the terminal pads 45.

Accordingly, as shown in FIGS. 17 and 18, a thermally enhanced wiring board 200 is accomplished and includes an isolator 10, a resin core 22, a squeezed out adhesive 225, a thermal base 40, contact pads 43, terminal pads 45 and routing circuitries 47. The resin core 22 is mechanically connected to the isolator 10 by the squeezed out adhesive 225. The thermal base 40 includes the first metal film 112, the first metal layer 222 and the joint layer 41, and has a first thickness T1 where it contacts the isolator 10, a second thickness T2 where it contacts the adhesive 225, a third thickness T3 where it contacts the resin core 22, and a flat surface that faces in the downward direction. In this illustration, the first thickness T1 and the third thickness T3 is larger than the second thickness T2, and the first thickness T1 is equal to the third thickness T3. The contact pads 43 on the isolator 10 can serve as electrical contacts for chip attachment, and the terminal pads 45 on the resin core 22 can serve as electrical contacts for external connections. The routing circuitries 47 provide electrical connections between the contact pads 43 and the terminal pads 25.

### Embodiment 3

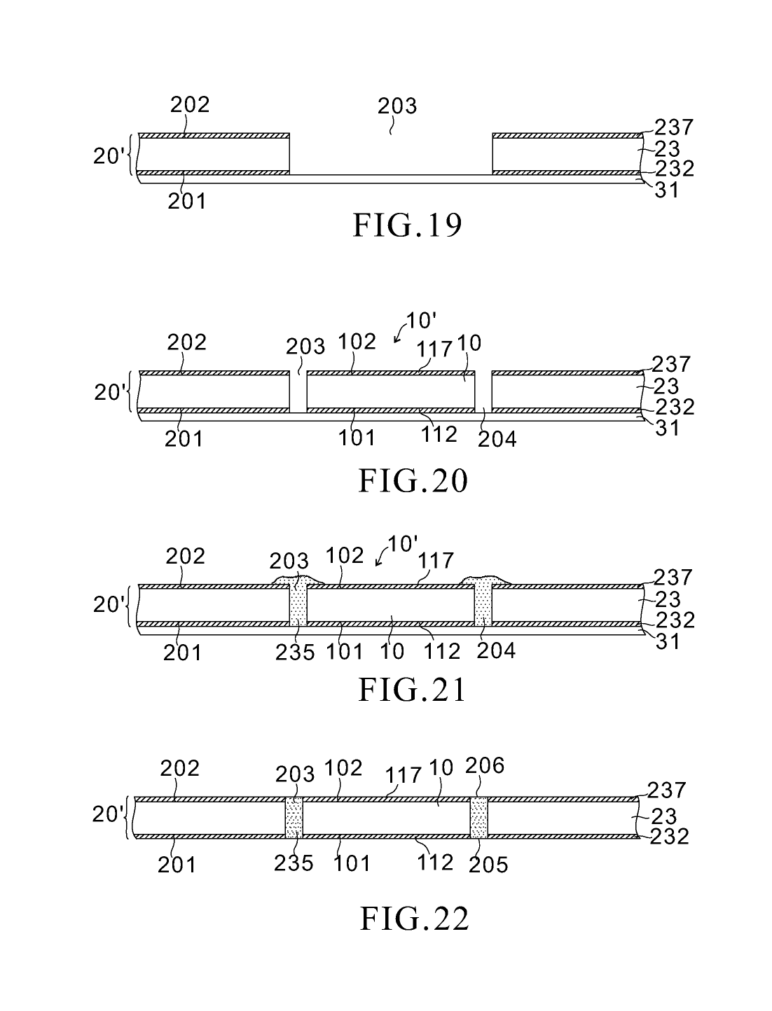

FIGS. 19-24 are schematic views showing yet another method of making a thermally enhanced wiring board in which a laminate substrate having an aperture is bonded to a metallized isolator by an adhesive dispensing process in accordance with yet another embodiment of the present invention.

For purposes of brevity, any description in the aforementioned Embodiments is incorporated herein insofar as the same is applicable, and the same description need not be repeated.

FIG. 19 is a cross-sectional view of a laminate substrate 20′ attached to a carrier film 31. The laminate substrate 20′ includes a resin core 23, first and second metal layers 232, 237 respectively disposed on opposite first and second sides 201, 203 of the resin core 23, and an aperture 203 that extends through the resin core 23, the first metal layer 232 and the second metal layer 237. The resin core 23 typically is made of epoxy resin, glass-epoxy, polyimide or the like, and has a thickness of 0.4 mm. The first and second metal layers 232, 237 each have a planar surface and typically are made of copper, and each has a thickness of 35 microns. In this illustration, the laminate substrate 20′ is attached to the carrier film 31 with the first metal layer 232 in contact with the carrier film 31.

FIG. 20 is a cross-sectional view of the structure with the metallized isolator 10′ of FIG. 2 attached to the carrier film 31. The metallized isolator 10′ is aligned with and inserted into the aperture 203 of the laminate substrate 20′ with the first metal film 112 facing towards the carrier film 31, and is attached on the carrier film 31 without contacting the laminate substrate 20′. As a result, a gap 204 is located in the aperture 203 between the metallized isolator 10′ and the laminate substrate 20′. The gap 204 laterally surrounds the metallized isolator 10′ and is laterally surrounded by the laminate substrate 20′.

FIG. 21 is a cross-sectional view of the structure with an adhesive 235 dispensed in the gap 204. The adhesive 235 fills the gap 204 and provides a secure robust mechanical bond between the metallized isolator 10′ and the laminate substrate 20′. In this illustration, the adhesive 235 also rises slightly above the gap 204 and overflows onto the top surfaces of the second metal film 117 and the second metal layer 237. FIG. 22 is a cross-sectional view of the structure after removal of excess adhesive and the carrier film 31. The excess adhesive on the second metal film 117 and second metal layer 237 is removed by lapping/grinding to create a smoothed lapped top surface. The carrier film 31 is detached from the first metal film 112, the first metal layer 232 and the adhesive 235 to expose the first metal film 112 and the first metal layer 232. Accordingly, the adhesive 235 has a first surface 205 essentially coplanar with the first metal film 112 and the first metal layer 232 in the downward direction, and an opposite second surface 206 essentially coplanar with the second metal film 117 and the second metal layer 237 in the upward direction.

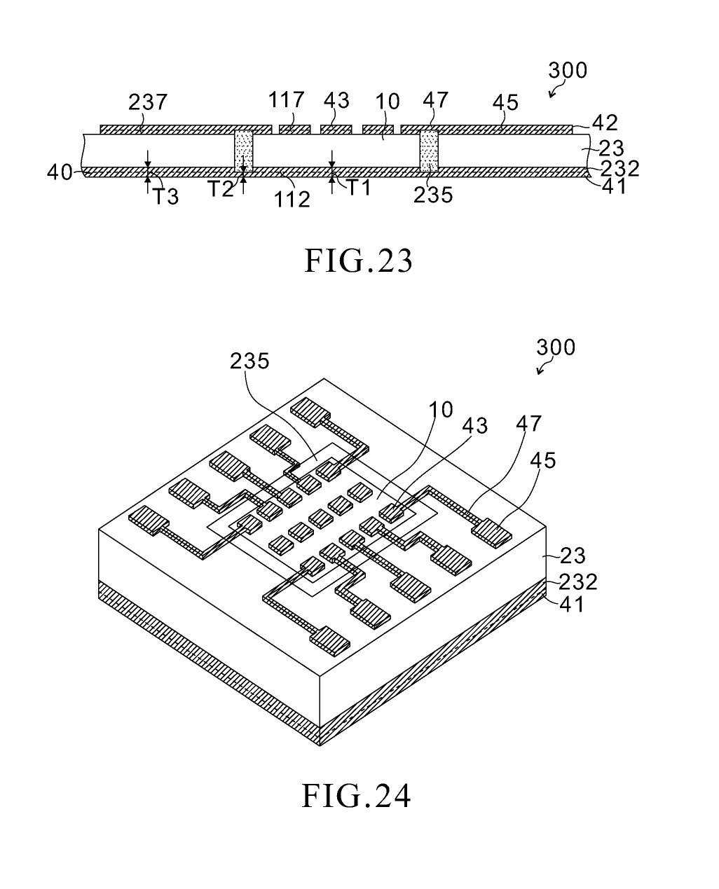

FIGS. 23 and 24 are cross-sectional and top perspective views, respectively, of the structure provided with a continuous thermally conductive joint layer 41, contact pads 43, terminal pads 45 and routing circuitries 47. The bottom surface of the structure is metallized to form the joint layer 41 that contacts and covers the first metal film 112 on the isolator 10, the first metal layer 232 on the resin core 23 and the adhesive 235 from below. Also, the top surface of the structure is metallized to form a plated layer 42, followed by a metal patterning process to form the contact pads 43, the terminal pads 45 and the routing circuitries 47. The contact pads 43 and the terminal pads 45 are disposed on the second side 102 of the isolator 10 and the second side 202 of the resin core 23, respectively. The routing circuitries 47 extend laterally on the second side 102 of the isolator 10, the second surface 206 of the adhesive 235 and the second side 202 of the resin core 23 and electrically connect the contact pads 43 and the terminal pads 45.

Accordingly, as shown in FIGS. 23 and 24, a thermally enhanced wiring board 300 is accomplished and includes an isolator 10, a resin core 23, an adhesive 235, a thermal base 40, contact pads 43, terminal pads 45 and routing circuitries 47. The resin core 23 is mechanically connected to the isolator 10 by the adhesive 235. The thermal base 40 includes the first metal film 112, the first metal layer 232 and the joint layer 41 and has a first thickness T1 where it contacts the isolator 10, a second thickness T2 where it contacts the adhesive 235, a third thickness T3 where it contacts the resin core 23, and a flat surface that faces in the downward direction. In this illustration, the first thickness T1 and the third thickness T3 is larger than the second thickness T2, and the first thickness T1 is equal to the third thickness T3. The contact pads 43 can serve as electrical contacts for chip attachment, and the terminal pads 45 can serve as electrical contacts for external connections. The routing circuitries 47 provide electrical connections between the contact pads 43 and the terminal pads 45.

### Embodiment 4

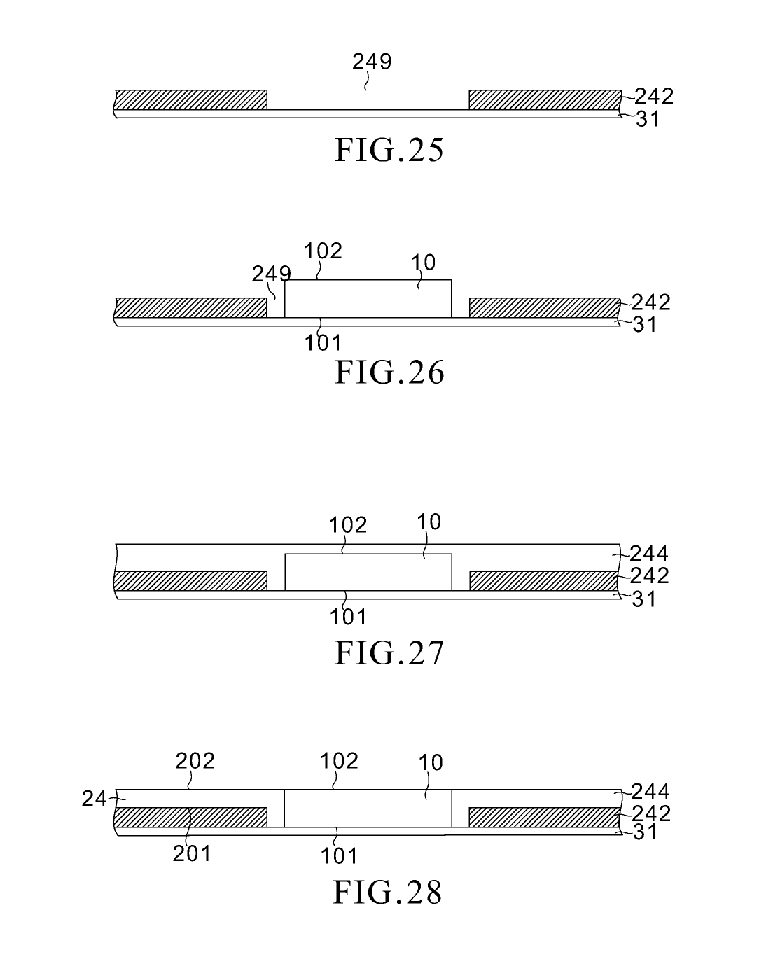

FIGS. 25-31 are schematic views showing yet another method of making a thermally enhanced wiring board with a dielectric layer laterally covering sidewalls of an isolator in accordance with yet another embodiment of the present invention.

For purposes of brevity, any description in the aforementioned Embodiments is incorporated herein insofar as the same is applicable, and the same description need not be repeated.

FIG. 25 is a cross-sectional view of the structure with a metal plate 242 on a carrier film 31. The metal plate 242 includes an opening 249 and is attached to the carrier film 31 by the adhesive property of the carrier film 31. The metal plate 242 can be made of copper, aluminum, nickel or other thermally conductive material. In this embodiment, the metal plate 242 is a copper plate with a thickness of 0.2 mm. The opening 249 can be formed by punching, stamping, etching or mechanical routing, and typically has a dimension that is almost the same or a little larger than a subsequently disposed isolator.

FIG. 26 is a cross-sectional view of the structure with the isolator 10 of FIG. 1 attached to a carrier film 31. The isolator 10 is partially inserted into the opening 249 of the metal plate 242 and is attached to the carrier film 31 with the first side 101 in contact with the carrier film 31. In this embodiment, the isolator 10 is a ceramic plate of 0.4 mm in thickness.

FIG. 27 is a cross-sectional view of the structure provided with a dielectric layer 244. The dielectric layer 244 can be deposited by a molding process or other methods such as lamination of epoxy or polyimide. The dielectric layer 244 covers the isolator 10 and the metal plate 242 from above, laterally covers and surrounds and conformally coats the sidewalls of the isolator 10, and extends laterally from the isolator 10 to peripheral edges of the structure. Further, the dielectric layer 244 extends into a gap between the isolator 10 and the metal plate 242 and contacts the carrier film 31.

FIG. 28 is a cross-sectional view of the structure with the second side 102 of the isolator 10 exposed from above. The upper portion of the dielectric layer 244 can be removed by grinding. After the grinding, the isolator 10 and the dielectric layer 244 are coplanar with each other at a smoothed lapped top surface. Accordingly, the isolator 10 is incorporated with a resin core 24 that has a first side 201 bonded to the metal plate 242 and an opposite second side 202 essentially coplanar with the second side 102 of the isolator 10 in the upward direction.

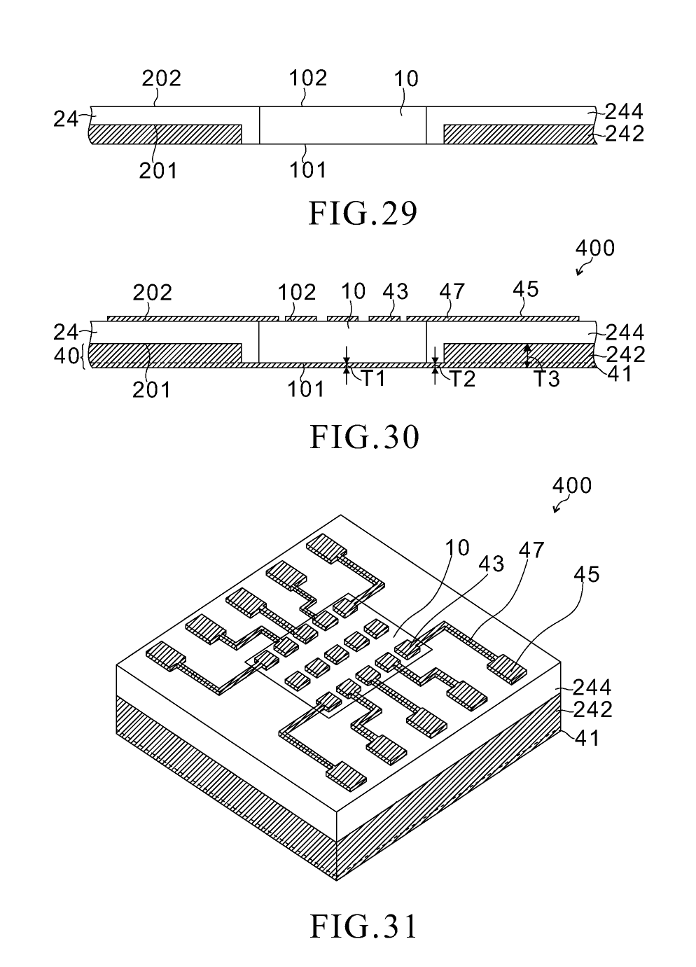

FIG. 29 is a cross-sectional view of the structure after removal of the carrier film 31. The carrier film 31 is detached from the isolator 10 and the metal plate 242 to expose the first side 101 of the isolator 10 and the metal plate 242.

FIGS. 30 and 31 are cross-sectional and top perspective views, respectively, of the structure provided with a continuous thermally conductive joint layer 41, contact pads 43, terminal pads 45 and routing circuitries 47. The joint layer 41, the contact pads 43, the terminal pads 45 and the routing circuitries 47 can be deposited by a sputtering process and then an electrolytic plating process to achieve desired thickness. Once the desired thickness is achieved, a metal patterning process is executed to form the contact pads 43, the terminal pads 45 and the routing circuitries 47. The joint layer 41 is an unpatterned metal layer that contacts and covers the isolator 10, the exposed resin core 24 and the metal plate 242 from below. The contact pads 43 and the terminal pads 45 are disposed on the second side 102 of the isolator 10 and the second side 202 of the resin core 24, respectively. The routing circuitries 47 extend laterally on the second side 102 of the isolator 10 and the second side 202 of the resin core 24 and electrically connect the contact pads 43 and the terminal pads 45.

Accordingly, as shown in FIGS. 30 and 31, a thermally enhanced wiring board 400 is accomplished and includes an isolator 10, a resin core 24, a thermal base 40, contact pads 43, terminal pads 45 and routing circuitries 47. The resin core 24 is directly integrated with the isolator 10 without additional adhesive. The thermal base 40 includes the metal plate 242 and the joint layer 41, and has a first thickness T1 where it contacts the isolator 10, a second thickness T2 where it contacts the resin core 24 that is larger than the first thickness T1, and a flat surface that faces in the downward direction. As an alternative, the structure may be formed to be devoid of the metal plate 242, and thus the thermal base can have an uniform thickness. The contact pads 43 on the second side 102 of the isolator 10 can serve as electrical contacts for chip connection. The terminal pads 45 on the second side 202 of the resin core 24 can serve as electrical contacts for external connection. The routing circuitries 47 contact and provide electrical connections between the contact pads 43 and the terminal pads 45.

As illustrated in the aforementioned embodiments, a distinctive thermally enhanced wiring board is configured to exhibit improved thermal performance and reliability. In a preferred embodiment, the thermally enhanced wiring board includes an isolator, a resin core, a thermal base, contact pads, terminal pads and routing circuitries, wherein (i) the isolator has opposite planar first and second sides; (ii) the resin core laterally covers and surrounds the isolator and has a first side facing towards the same direction as the first side of the isolator and an opposite second side facing towards the same direction as the second side of the isolator; (iii) the thermal base is formed on the first side of the isolator and the first side of the resin core to provide a thermal dissipation platform that contacts the first side of the isolator and laterally extends beyond peripheral edges of the isolator; (iv) the contact pads are formed on the second side of the isolator; (v) the terminal pads are formed on the second side of the resin core; and (vi) the routing circuitries electrically connect the contact pads to the terminal pads.

The isolator is made of a thermally conductive and electrically insulating material and typically has high elastic modulus and low coefficient of thermal expansion (for example, 2×10⁻⁶ K⁻¹ to 10×10⁻⁶ K⁻¹). As a result, the isolator provides a CTE-compensated contact interface for a semiconductor chip, and thus internal stresses caused by CTE mismatch can be largely compensated or reduced. Further, the isolator also provides primary heat conduction for the chip so that the heat generated by the chip can be conducted away.

The resin core can be bonded to the isolator by a lamination process or an adhesive dispensing process. For instance, a metallized isolator can be provided by depositing first and second metal films (typically copper films) respectively on opposite first and second sides of the isolator, and then be inserted into an aperture of a stacking structure having a binding film disposed between a first metal layer and a second metal layer, followed by applying heat and pressure in a lamination process to cure the binding film. By the lamination process, the binding film can provide a secure robust mechanical bond between the first metal layer and the second metal layer, and an adhesive squeezed out from the binding film laterally covers and surrounds and conformally coats sidewalls of the metallized isolator. As a result, a resin core is formed to have opposite first and second sides respectively bonded to the first and second metal layers (typically copper layers), and is adhered to the sidewalls of the isolator by the squeezed out adhesive. As an alternative, the metallized isolator may be inserted into an aperture of a laminate substrate having first and second metal layers on opposite first and second sides of a resin core, and then an adhesive is dispensed between and contacts the sidewalls of the metallized isolator and the aperture sidewalls of the laminate substrate. Accordingly, in one aspect of the present invention, the resin core is bonded to sidewalls of the isolator by an adhesive that may be the squeezed out adhesive or the dispensed adhesive as mentioned above. Preferably, the adhesive has a first surface substantially coplanar with the first metal film on the isolator and the first metal layer on the resin core in the first vertical direction, and an opposite second surface substantially coplanar with the second metal film on the isolator and the second metal layer on the resin core in the second vertical direction. For the convenience of description, the direction in which the first side of the isolator faces is defined as the first vertical direction, and the direction in which the second side of the isolator faces is defined as the second vertical direction. In the foregoing description of the Embodiments, the first and second vertical directions are downward and upward directions, respectively.

As another aspect of the present invention, the resin core may be formed by depositing a dielectric layer that laterally surrounds and conformally coats and contacts sidewalls of the isolator. By a molding process or other methods such as lamination of epoxy or polyimide, the resin core contacts and conformally coats and is directly integrated with the sidewalls of the isolator without additional adhesive and preferably is substantially coplanar with the isolator in the second vertical direction. Further, a metal plate may be bonded to one side of the resin core by the above molding process or resin lamination process. For instance, the isolator may be partially inserted into an opening of a metal plate, followed by depositing a dielectric layer that covers the sidewalls of the isolator and the metal plate and extends into a gap between the isolator and the metal plate. As a result, the resin core can have a first side bonded to the metal plate and an opposite second side substantially coplanar with the second side of the isolator. Preferably, the metal plate is substantially coplanar with the dielectric layer and the isolator in the first vertical direction.

Before the aforementioned lamination or adhesive dispensing or molding process, a carrier film (typically an adhesive tape) may be used to provide temporary retention force. For instance, the carrier film can temporally adhere to the first or second metal film of the metallized isolator and the first or second metal layer of the stacking structure to retain the metallized isolator within the aperture of the stacking structure, followed by the lamination process of the stacking structure. For the adhesive dispensing case, the metallized isolator can be retained within the aperture of the laminate substrate by the carrier film that temporally adheres to the first or second metal film of the metallized isolator and the first or second metal layer of the laminate substrate, and then the adhesive can be dispensed in the gap between the metallized isolator and the laminate substrate to provide a secure robust mechanical bond therebetween. As for the molding case, the carrier film can adhere to the isolator and the optional metal plate, followed by depositing the dielectric layer that covers the sidewalls of the isolator, the carrier film and the optional metal plate. After the isolator is bonded with the resin core as mentioned above, the carrier film is detached therefrom before the step of depositing the joint layer.

The thermal base can be an unpatterned metal layer (typically a copper layer) and cover and contact the first side of the isolator and the first side of the resin core in the first vertical direction. In a preferred embodiment, the thermal base extends to the peripheral edges of the wiring board to provide a large thermal dissipation surface area. Accordingly, the thermal base can provide a horizontal thermal dissipation platform that is larger than the isolator. In accordance with the aspect of the resin core bonded to the isolator by an adhesive, the thermal base can be formed by an electroless plating process to deposit a thermally conductive joint layer on the second surface of the adhesive, the first metal film on the isolator, and the first metal layer on the resin core. Further, the electroless plating process may be followed by an electrolytic plating process to achieve desired metal thickness. As a result, the thermal base consists of the first metal film, the first metal layer and the joint layer. The joint layer can contact and connect the first metal film on the isolator and the first metal layer on the resin core so that the isolator is thermally conductible to a surrounding heat spreader composed of the first metal layer and a portion of the joint layer adjacent to the first metal layer. In this case, the thermal base can have a first thickness where it contacts the isolator, a second thickness where it contacts the adhesive, a third thickness where it contacts the resin core, and a flat surface that faces in the first vertical. In a preferred embodiment, the first thickness and the third thickness are larger than the second thickness, and the first thickness may be equal to or different from the second thickness. In accordance with another aspect of the resin core directly integrated with the isolator without additional adhesive, the thermal base can be formed by a sputtering process to deposit a thermally conductive joint layer that covers the resin core and the isolator in the first vertical direction. Further, the sputtering process may be followed by an electrolytic plating process to achieve desired metal thickness. As such, the joint layer is thermally conductible to the isolator and provides a thermal base that can have a uniform thickness when no metal layer is bonded to the first side of the isolator or the first side of the resin core. Also, the thermal base may have a first thickness where it contacts the isolator, a second thickness where it contacts the resin core that is different from the first thickness, and a flat surface that faces in the first vertical. For instance, as the first side of the resin core is bonded to a metal plate, the thermal base has a combined thickness of the metal plate and the joint layer at the portion that contacts the resin core, resulting in the second thickness being larger than the first thickness. In any case, the thermal base is thermally conductible to the isolator and laterally extends beyond peripheral edges of the isolator.

The contact pads are disposed on the second side of the isolator and can serve as electrical contacts for chip attachment. The terminal pads are disposed on the second side of the resin core and can serve as electrical contacts for external connection. The routing circuitries contact and provide an electrical connection between the contact pads and the terminal pads. The contact pads, the terminal pads and the routing circuitries can be formed by metal deposition and then metal patterning. For the aspect of the resin core bonded to the isolator by an adhesive, the contact pads, the terminal pads and the routing circuitries typically are deposited by an electroless plating process and then an electrolytic plating process. Specifically, a plated layer can be deposited on and cover the second metal film on the isolator, the second surface of the adhesive and the second metal layer on the resin core in the second vertical direction, followed by a patterning process to form the contact pads on the second side of the isolator, the terminal pads on the second side of the resin core, and the routing circuitries that are disposed on the second surface of the adhesive and laterally extend to the contact pads and the terminal pads. As a result, the contact pads have a combined thickness of the second metal film and the plated layer; the terminal pads have a combined thickness of the second metal layer and the plated layer; and the routing circuitries have a thickness of the plated layer where it contacts the adhesive, a combined thickness of the second metal film and the plated layer where it contacts the isolator, and a combined thickness of the second metal layer and the plated layer where it contacts the resin core. As for the aspect of the resin core directly integrated with the isolator without additional adhesive, the contact pads, the terminal pads and the routing circuitries typically are deposited by a sputtering process and then an electrolytic plating process. After the deposition process, a patterning process is executed to form the contact pads on the second side of the isolator, the terminal pads on the second side of the resin core, and the routing circuitries that are disposed on the dielectric layer and laterally extend to the contact pads and the terminal pads. In this case, the contact pads, the terminal pads and the routing circuitries typically have the same thickness.

The present invention also provides a semiconductor assembly in which a semiconductor device such as LED chip is mounted on the contact pads of the aforementioned wiring board. Specifically, the semiconductor device can be electrically connected to the wiring board using various using a wide variety of connection media including gold or solder bumps on the contact pads of the wiring board. Accordingly, the isolator incorporated in the wiring board can provide CTE-compensated contact interface for the semiconductor device, and the heat generated by the semiconductor device can be transferred to the isolator and further spread out to a surrounding heat spreader underneath the resin core.

The assembly can be a first-level or second-level single-chip or multi-chip device. For instance, the assembly can be a first-level package that contains a single chip or multiple chips. Alternatively, the assembly can be a second-level module that contains a single package or multiple packages, and each package can contain a single chip or multiple chips. The chip can be a packaged or unpackaged chip. Furthermore, the chip can be a bare chip, or a wafer level packaged die, etc.

The term “cover” refers to incomplete or complete coverage in a vertical and/or lateral direction. For instance, in the position that the joint layer faces the downward direction, the dielectric layer covers the joint layer in the upward direction regardless of whether another element such as the metal plate is between the dielectric layer and the joint layer.

The phrases “mounted on” and “attached on” include contact and non-contact with a single or multiple support element(s). For instance, the isolator can be attached on the carrier film regardless of whether it contacts the carrier film or is separated from the carrier film by an adhesive.

The phrases “electrical connection”, “electrically connect(s)” and “electrically connected” refer to direct and indirect electrical connection. For instance, the contact pad is electrically connected to the terminal pad by the routing circuitry but is spaced from and does not contact the terminal pad.

The “first vertical direction” and “second vertical direction” do not depend on the orientation of the wiring board, as will be readily apparent to those skilled in the art. For instance, the first side of the isolator faces the first vertical direction and the second side of the isolator faces the second vertical direction regardless of whether the wiring board is inverted. Thus, the first and second vertical directions are opposite one another and orthogonal to the lateral directions, and a lateral plane orthogonal to the first and second vertical directions intersects laterally aligned elements. Furthermore, the first vertical direction is the downward direction and the second vertical direction is the upward direction in the position that the joint layer faces the downward direction, and the first vertical direction is the upward direction and the second vertical direction is the downward direction in the position that the joint layer faces the upward direction.

The thermally enhanced wiring board according to the present invention has numerous advantages. The isolator provides CTE-compensated contact interface for chip attachment and also establish a heat dissipation pathway from the chip to the surrounding heat spreader underneath the resin core. The resin core provides mechanical support and serves as a spacer between the wiring layer and the heat spreader. The heat spreader provides a horizontal platform that is larger than the isolator so that the heat transferred to the isolator can be further spread out. The wiring layer provides signal transmission and electrical routing of the board. The wiring board made by this method is reliable, inexpensive and well-suited for high volume manufacture.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A method of making a thermally enhanced wiring board having isolator incorporated therein, comprising steps of:
providing an isolator having opposite planar first and second sides, wherein the isolator is made of a thermally conductive and electrically insulating material;
depositing first and second metal films respectively on the first and second sides of the isolator to provide a metallized isolator;
providing a stacking structure that includes first and second metal layers, a binding film disposed between the first and second metal layers, and an aperture formed in the stacking structure, wherein the first and second metal layers each have a planar surface;
inserting the metallized isolator into the aperture of the stacking structure with the first metal film on the isolator and the first metal layer of the stacking structure facing towards the same direction, and then curing the binding film to form a resin core that has a first side bonded to the first metal layer and an opposite second side bonded to the second metal layer, wherein the stacking structure is adhered to sidewalls of the metallized isolator by an adhesive squeezed out from the binding film into a gap between the stacking structure and the metallized isolator;
removing an excess portion of the squeezed out adhesive, thereby the adhesive having a first surface substantially coplanar with the first metal film on the isolator and the first metal layer of the stacking structure, and an opposite second surface substantially coplanar with the second metal film on the isolator and the second metal layer of the stacking structure;
depositing a continuous thermally conductive joint layer on the first surface of the adhesive, the first metal film and the first metal layer, so as to connect the first metal film on the isolator to the first metal layer on the resin core; and
forming contact pads on the second side of the isolator, terminal pads on the second side of the resin core, and routing circuitries that electrically connect the contact pads to the terminal pads.

2. The method of claim 1, wherein the step of inserting the metallized isolator into the aperture of the stacking structure includes attaching a carrier film to the stacking structure before inserting the metallized isolator and detaching the carrier film after curing the binding film.

3. The method of claim 1, wherein the step of depositing the joint layer includes an electroless plating.

4. The method of claim 1, wherein the isolator has a coefficient of thermal expansion between 2×10⁻⁶ K⁻¹ and 10×10⁻⁶ K⁻¹.

5. A method of making a thermally enhanced wiring board having isolator incorporated therein, comprising steps of:
providing an isolator having opposite planar first and second sides, wherein the isolator is made of a thermally conductive and electrically insulating material;
depositing first and second metal films respectively on the first and second sides of the isolator to provide a metallized isolator;
providing a laminate substrate that includes a resin core, first and second metal layers respectively disposed on opposite first and second sides of the resin core, and an aperture formed in the laminate substrate, wherein the first and second metal layers each have a planar surface;
inserting the metallized isolator into the aperture of the laminate substrate with the first metal film on the isolator and the first metal layer of the laminate substrate facing towards the same direction, and then dispensing an adhesive into a gap between the metallized isolator and the laminate substrate within the aperture to adhere sidewalls of the metallized isolator to sidewalls of the aperture;
removing an excess portion of the adhesive, thereby the adhesive having a first surface substantially coplanar with the first metal film on the isolator and the first metal layer of the laminate substrate, and an opposite second surface substantially coplanar with the second metal film on the isolator and the second metal layer of the laminate substrate;
depositing a continuous thermally conductive joint layer on the first surface of the adhesive, the first metal film and the first metal layer, to connect the first metal film on the isolator to the first metal layer on the resin core; and
forming contact pads on the second side of the isolator, terminal pads on the second side on the resin core, and routing circuitries that electrically connect the contact pads to the terminal pads.

6. The method of claim 5, wherein the step of inserting the metallized isolator into the aperture of the laminate substrate includes attaching a carrier film to the laminate substrate before inserting the metallized isolator and detaching the carrier film after dispensing the adhesive.

7. A method of making a thermally enhanced wiring board having isolator incorporated therein, comprising steps of:
attaching an isolator on a carrier film, wherein the isolator is made of a thermally conductive and electrically insulating material and has opposite planar first and second sides;
depositing a dielectric layer that covers the isolator and the carrier film;
removing a portion of the dielectric layer to form a resin core that has a first side and an opposite second side substantially coplanar with the second side of the isolator, and detaching the carrier film therefrom;
depositing a continuous thermally conductive joint layer on the first side of the isolator and the first side of the resin core; and
forming contact pads on the second side of the isolator, terminal pads on the second side of the resin core, and routing circuitries that electrically connect the contact pads to the terminal pads.

8. The method of claim 7, further comprising a step of attaching a metal plate with an opening on the carrier film before the step of depositing the dielectric layer, wherein the isolator is partially inserted into the opening of the metal plate, and the dielectric layer is also deposited to cover the metal plate.

9. The method of claim 7, wherein the step of depositing the joint layer on the isolator and the resin core includes a sputtering process.
